(19) United States
(12) Patent Application Publication
(10) Pub. No.: US 2025/0081477 A1
(43) Pub. Date: Mar. 6, 2025

(54) INDUCTOR ELEMENT AND INTEGRATED CIRCUIT

(71) Applicant: Murata Manufacturing Co., Ltd., Kyoto-fu (JP)

(72) Inventors: Yoshimasa YOSHIOKA, Nagaokakyo-shi (JP); Taiga KATO, Nagaokakyo-shi (JP); Takaaki MIYASAKO, Nagaokakyo-shi (JP); Takayuki OKADA, Nagaokakyo-shi (JP)

(73) Assignee: Murata Manufacturing Co., Ltd., Kyoto-fu (JP)

(21) Appl. No.: 18/678,853

(22) Filed: May 30, 2024

(30) Foreign Application Priority Data
Aug. 28, 2023 (JP) 2023-138167

(51) Int. Cl. H01F 17/04; H01L 23/522; H01L 27/06

(52) U.S. Cl. CPC H10D 1/20; H01L 23/5227; H10D 84/811

(57) ABSTRACT

An inductor element includes an inductor wiring having an interruption portion in at least one place, a pair of external terminals that are connected to each of one side part and the other side part, which are located on both sides of the interruption portion, of the inductor wiring and that are exposed to an outside, at least one inductor variable resistance portion that is provided at the interruption portion, and at least one variable resistance terminal that is connected to the inductor variable resistance portion and that is exposed to the outside. The inductor variable resistance portion connects the one side part and the other side part, and changes a resistance value between the one side part and the other side part.

### CROSS-REFERENCE TO RELATED APPLICATION

This application claims benefit of priority to Japanese Patent Application No. 2023-138167, filed Aug. 28, 2023, the entire content of which is incorporated herein by reference.

### BACKGROUND

### Technical Field

The present disclosure relates to an inductor element and an integrated circuit including the inductor element.

### Background Art

In a power transmission system such as wireless power supply, there is a demand to expand a region where power transmission is possible. To expand the region where the power transmission is possible, for example, beamforming is performed by changing a phase of a phase shifter included in the power transmission system. To change the phase of the phase shifter, for example, it is conceivable to change impedance of an inductor element included in the phase shifter.

To change the impedance of the inductor element, for example, it is conceivable to implement a variable inductor, which is disclosed in Japanese Patent No. 6701923, Japanese Unexamined Patent Application No. 1996-162331, and Japanese Unexamined Patent Application No. 2010-272815, on the phase shifter as the inductor element. With a change in inductance of the variable inductor, it is possible to change the impedance of the variable inductor.

The variable inductor disclosed in Japanese Patent No. 6701923 includes a plurality of coil patterns, and a plurality of switches connected to the plurality of coil patterns with outer electrodes interposed therebetween. A combination of the coil patterns through which a current flows is changed according to on and off of each switch. Accordingly, the inductance of the variable inductor is set to a desired value.

The variable inductor disclosed in Japanese Unexamined Patent Application No. 1996-162331 includes a plurality of loop-shaped wiring layers having open ends, and an electric field effect transistor as a switch that opens/shorts the open end of each wiring layer. The inductance of the variable inductor is determined according to an open/short combination of the open ends of the respective wiring layers.

The variable inductor disclosed in Japanese Unexamined Patent Application No. 2010-272815 includes two inductors and a switch that sets a state between the two inductors to a conductive state or a non-conductive state. The inductance of the variable inductor is determined according to on and off of the switch.

### SUMMARY

In the variable inductor, which is disclosed in Japanese Patent No. 6701923, Japanese Unexamined Patent Application No. 1996-162331, and Japanese Unexamined Patent Application No. 2010-272815, the number of turns of the coil that functions and a line length thereof change according to the on and off of the switch. For this reason, the variable inductor increases in size. The size of the variable inductor can be reduced by reducing the number of coils included in the variable inductor. However, in this case, the variable inductor needs to be disposed in a plurality of stages in order to increase a variable range of the inductance. For this reason, it is not possible to avoid an increase in size of a device including the variable inductor as a whole.

Accordingly, the present disclosure provides an inductor element whose size increase can be suppressed.

An inductor element of one aspect of the present disclosure includes an inductor wiring having an interruption portion in at least one place, a pair of external terminals that are connected to each of one side part and the other side part, which are located on both sides of the interruption portion, of the inductor wiring and that are exposed to an outside, at least one inductor variable resistance portion that is provided at the interruption portion, and at least one variable resistance terminal that is connected to the inductor variable resistance portion and that is exposed to the outside. The inductor variable resistance portion connects the one side part and the other side part, and changes a resistance value between the one side part and the other side part.

According to the present disclosure, it is possible to provide the inductor element whose size increase can be suppressed.

### BRIEF DESCRIPTION OF THE DRAWINGS

FIG. 1 is a functional block diagram of a phased array antenna including an inductor element of the present disclosure;

FIGS. 2A to 2C are equivalent circuit diagrams of an inductor element according to a first embodiment of the present disclosure;

FIG. 3 is a schematic plan view of the inductor element according to the first embodiment of the present disclosure;

FIG. 4 is a schematic cross-sectional view of a cross section taken along a line A-A in FIG. 3;

FIG. 5 is a schematic cross-sectional view describing a method of manufacturing the inductor element according to the first embodiment of the present disclosure;

FIG. 6 is a schematic cross-sectional view describing the method of manufacturing the inductor element according to the first embodiment of the present disclosure;

FIG. 7 is a schematic cross-sectional view describing the method of manufacturing the inductor element according to the first embodiment of the present disclosure;

FIG. 8 is a schematic plan view of an inductor element according to a second embodiment of the present disclosure;

FIG. 9 is a schematic plan view of an inductor element according to a third embodiment of the present disclosure;

FIG. 10 is a schematic cross-sectional view of a cross section corresponding to the cross section taken along the line A-A in FIG. 3 in an inductor element according to a fourth embodiment of the present disclosure;

FIG. 11 is a schematic cross-sectional view of a cross section corresponding to the cross section taken along the line A-A in FIG. 3 in a modification example of the inductor element according to the fourth embodiment of the present disclosure;

FIG. 12 is a schematic plan view of an inductor element according to a fifth embodiment of the present disclosure;

FIG. 13 is a schematic plan view of an integrated circuit according to a sixth embodiment of the present disclosure;

FIG. 14 is a schematic cross-sectional view of a cross section taken along a line B-B in FIG. 13;

FIG. 15 is an equivalent circuit diagram of an integrated circuit according to a sixth embodiment of the present disclosure;

FIG. 16 is a schematic cross-sectional view of a cross section corresponding to the cross section taken along the line B-B in FIG. 13 in a modification example of the integrated circuit according to the sixth embodiment of the present disclosure;

FIG. 17 is a schematic cross-sectional view of a cross section corresponding to the cross section taken along the line A-A in FIG. 3 in an inductor element according to a seventh embodiment of the present disclosure; and

FIG. 18 is a schematic cross-sectional view of a cross section corresponding to the cross section taken along the line A-A in FIG. 3 in an inductor element according to an eighth embodiment of the present disclosure.

### DETAILED DESCRIPTION

Hereinafter, an example of the present disclosure will be described with reference to accompanying drawings. The following description is essentially merely an example, and is not intended to limit the present disclosure, any application thereof, or any use thereof. Further, the drawings are schematic, and a ratio of each dimension and the like do not necessarily match actual ones. Further, terms indicating specific directions or positions as necessary (for example, terms including “upper”, “lower”, “right”, “left”, “front”, and “rear”) are used in the following description. However, the use of the terms indicating the specific directions or positions is for easy understanding of the present disclosure with reference to the drawings, and the technical scope of the present disclosure is not limited by the meaning of the terms.

### First Embodiment

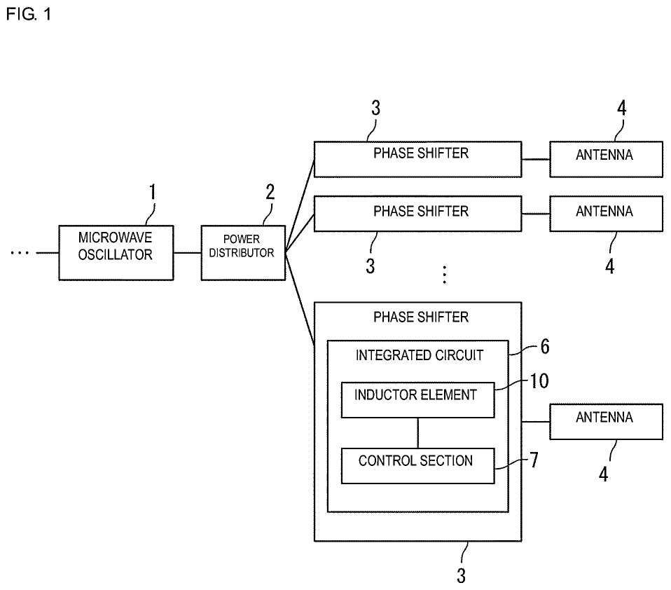

FIG. 1 is a functional block diagram of a phased array antenna including an inductor element of the present disclosure.

As shown in FIG. 1, the phased array antenna includes a microwave oscillator 1, a power distributor 2, a plurality of phase shifters 3, and a plurality of antennas 4. The microwave oscillator 1 transmits a microwave to the power distributor. The power distributor 2 distributes the microwave input from the microwave oscillator 1 into a plurality of microwaves, and outputs the distributed microwaves to each of the plurality of phase shifters 3. Each of the plurality of phase shifters 3 changes a phase of the microwave input from the power distributor 2. The microwave output from the phase shifter 3 is transmitted to the outside via the antenna 4.

Each of the plurality of phase shifters 3 includes an integrated circuit 6. The integrated circuit 6 includes an inductor element 10 and a control section 7. The inductor element 10 will be described in detail below. The control section 7 is configured of a known electronic circuit, and controls a resistance value of an inductor variable resistance portion 30 included in the inductor element 10.

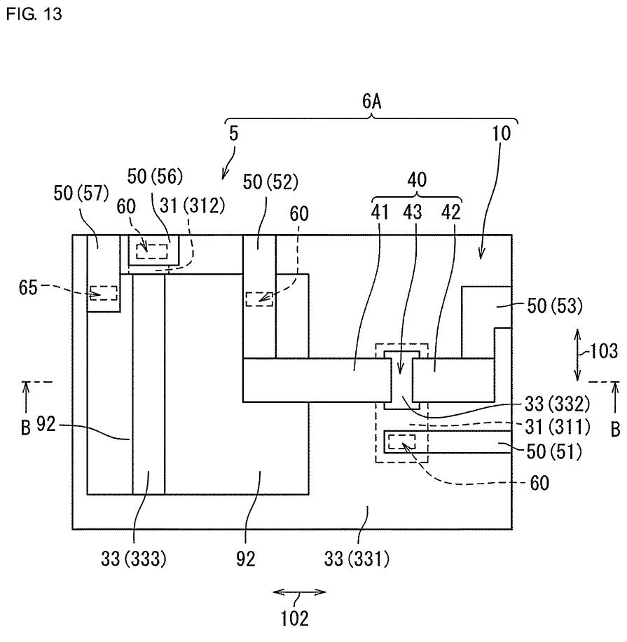

The application of the phase shifter 3 is not limited to the phased array antenna. The application of the inductor element 10 and a capacitor element 5 (refer to FIGS. 13 to 16), which will be described below, is not limited to the phase shifter 3. The number of the inductor elements 10 included in the integrated circuit 6 is not limited to one.

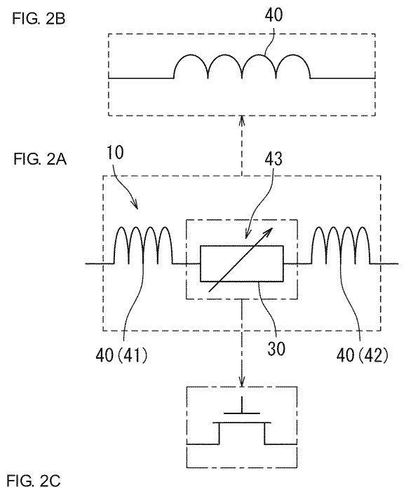

FIGS. 2A to 2C are equivalent circuit diagrams of an inductor element according to a first embodiment of the present disclosure. As shown in FIG. 2A, the inductor element 10 includes an inductor wiring 40 and the inductor variable resistance portion 30. The inductor wiring 40 is divided into two parts (one side part 41 and the other side part 42) by an interruption portion 43. In other words, the one side part 41 and the other side part 42 of the inductor wiring 40 are located on both sides of the interruption portion 43. The interruption portion 43 is provided with the inductor variable resistance portion 30. The inductor variable resistance portion 30 is connected to the one side part 41 and the other side part 42. Accordingly, the one side part 41 and the other side part 42 are conducted to each other. The one side part 41, the inductor variable resistance portion 30, and the other side part 42 configure one inductor, as shown in FIG. 2B.

The inductor variable resistance portion 30 changes the resistance value with respect to a current that flows in the inductor wiring 40. In the first embodiment, the inductor variable resistance portion 30 is a metal-oxide-semiconductor field-effect transistor (MOSFET), as shown in FIG. 2C.

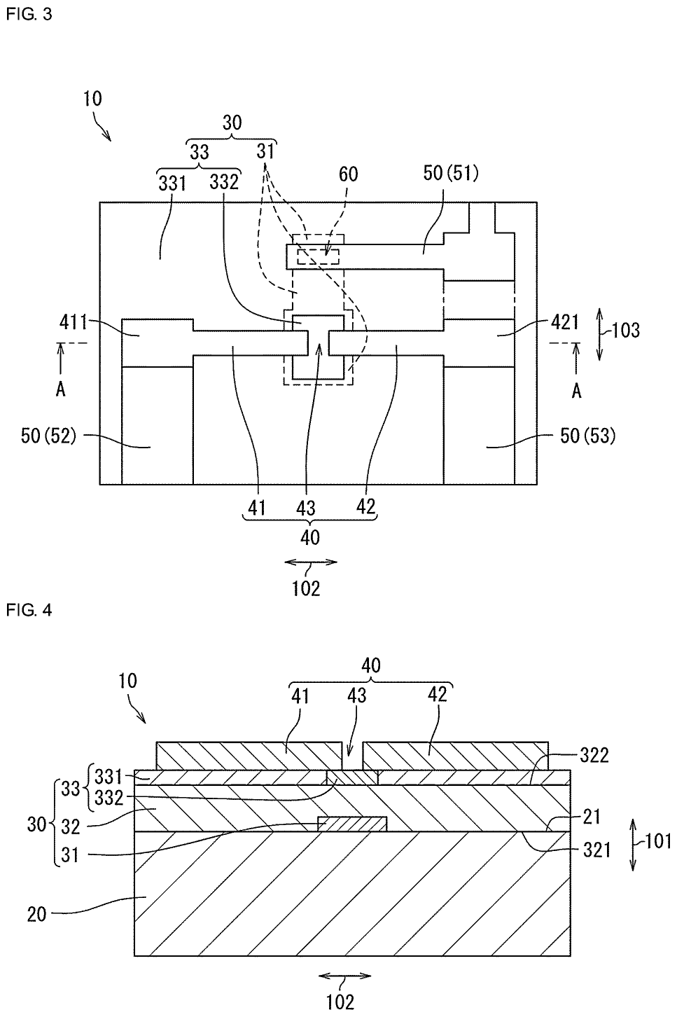

FIG. 3 is a schematic plan view of the inductor element according to the first embodiment of the present disclosure. FIG. 4 is a schematic cross-sectional view of a cross section taken along a line A-A in FIG. 3.

As shown in FIGS. 3 and 4, the inductor element 10 includes a substrate 20, the inductor variable resistance portion 30 laminated on the substrate 20, and the inductor wiring 40 and a wiring portion 50, which are laminated on the inductor variable resistance portion 30. A direction in which the substrate 20, the inductor variable resistance portion 30, the inductor wiring 40, and the wiring portion 50 are laminated is a thickness direction 101 of the inductor element 10. In other words, the thickness direction 101 can also be said to be a thickness direction of each of the substrate 20, the inductor variable resistance portion 30, the inductor wiring 40, and the wiring portion 50.

In the first embodiment, the substrate 20 has a plate shape. A main surface 21 of the substrate 20 is a rectangle extending in a long-side direction 102 and a short-side direction 103. The long-side direction 102 and the short-side direction 103 are orthogonal to the thickness direction 101. The long-side direction 102 is a direction parallel to a long side of the rectangle, which is the shape of the main surface 21. The short-side direction 103 is a direction parallel to a short side of the rectangle, which is the shape of the main surface 21. The long-side direction 102 and the short-side direction 103 are orthogonal to each other. In the first embodiment, the substrate 20 is made of silicon (Si).

The inductor variable resistance portion 30 will be described in detail below. As described above, the inductor wiring 40 is interrupted into two parts at the interruption portion 43. One of the two parts is the one side part 41. The other of the two parts is the other side part 42. The interruption portion 43 refers to a space between the one side part 41 and the other side part 42. The one side part 41 has an electrode 411. The other side part 42 has an electrode 421. In FIGS. 3 and 4, the one side part 41 and the other side part 42 are schematically drawn in a straight line. However, the one side part 41 and the other side part 42 may have a shape that functions as an inductor, for example, a vortex shape, a meander shape, or a spiral shape. The inductor wiring 40 is made of a material having conductivity. The material having conductivity is, for example, gold (Au), silver (Ag), nickel (Ni), copper (Cu), aluminum (Al), or an alloy or compound containing these metals. In the first embodiment, the inductor wiring 40 is made of copper (Cu).

The inductor variable resistance portion 30 is a MOSFET, and includes a gate electrode 31, an oxide film 32, and a channel layer 33.

The gate electrode 31 is laminated on the main surface 21 of the substrate 20. As shown in FIG. 3, in a plan view as viewed from the thickness direction 101, the gate electrode 31 includes a region overlapping the interruption portion 43 of the inductor wiring 40. In other words, in a plan view, the gate electrode 31 is at a position that overlaps the interruption portion 43 of the inductor wiring 40. As shown in FIG. 4, a part of the gate electrode 31 faces the interruption portion 43 in the thickness direction 101 with the oxide film 32 and the channel layer 33 interposed therebetween. As shown in FIG. 3, the gate electrode 31 extends in the short-side direction 103 from the region overlapping the interruption portion 43 in a plan view. The gate electrode is obtained by implanting impurities into polysilicon (Poly-Si) at a high concentration. The gate electrode is not limited to polysilicon (Poly-Si), and may be made of, for example, a conductor such as copper (Cu), silver (Ag), platinum (Pt), or gold (Au).

As shown in FIG. 4, the oxide film 32 has one main surface 321 and the other main surface 322. The other main surface 322 is a surface opposite to the one main surface 321 in the thickness direction 101. The oxide film 32 is laminated on the substrate 20 such that one main surface 321 is in contact with the main surface 21 of the substrate 20. One main surface 321 of the oxide film 32 covers the gate electrode 31. In other words, the gate electrode 31 is provided on a side of the one main surface 321 of the oxide film 32 in contact with the oxide film 32.

The oxide film 32 includes a High-k material. In the first embodiment, the entire oxide film 32 is made of hafnium oxide (HfO₂) which is the High-k material. The oxide film 32 may be made of the High-k material other than hafnium oxide. A part of the oxide film 32 may be made of the High-k material. The oxide film 32 may be made of a material other than the High-k material, for example, silicon dioxide (SiO₂) or another high-dielectric constant material.

The channel layer 33 is laminated on the other main surface 322 of the oxide film 32. In other words, the channel layer 33 is provided on a side of the other main surface 322 of the oxide film 32 in contact with the oxide film 32.

In the first embodiment, the entire channel layer 33 is made of amorphous silicon. A part of the channel layer 33 may be made of amorphous silicon. The material constituting the channel layer 33 is not limited to amorphous silicon, and may be, for example, a metal oxide semiconductor.

The channel layer 33 has an undoped region 331 and a doped region 332. The doped region 332 is a region in the channel layer 33 in which impurities are doped by a known method and thus a high concentration impurity region is formed. The undoped region 331 is a region in the channel layer 33 in which impurities are not doped. The impurity is an element having a valence of 5, such as phosphorus or arsenic, in a case where the channel layer 33 is an N type semiconductor, and an element having a valence of 3, such as boron or aluminum, in a case where the channel layer 33 is a P type semiconductor.

As shown in FIGS. 3 and 4, in a plan view, the doped region 332 overlaps the entire interruption portion 43, a part of the one side part 41, and a part of the other side part 42. In the first embodiment, the part of the one side part 41 is an end portion of the one side part 41 opposite to the electrode 411. In the first embodiment, the part of the other side part 42 is an end portion of the other side part 42 opposite to the electrode 421. Accordingly, the doped region 332 is in contact with both the one side part 41 and the other side part 42. Therefore, the one side part 41 and the other side part 42 are connected to each other with the doped region 332 interposed therebetween.

In a plan view, the doped region 332 overlaps the gate electrode 31. The doped region 332 faces the gate electrode 31 in the thickness direction 101 with the oxide film 32 interposed therebetween.

The inductor wiring 40 and the wiring portion 50 are laminated on the channel layer 33. The inductor wiring 40 and the wiring portion 50 are exposed to the outside with respect to the substrate 20 and the inductor variable resistance portion 30. The inductor wiring 40 and the wiring portion 50 are provided on a side of the channel layer 33 opposite to the oxide film 32 in the thickness direction 101 and are in contact with the channel layer 33. The inductor wiring 40 and the wiring portion 50 are integrally formed, and thus a boundary therebetween is not clear. For convenience, in a drawing in which both the inductor wiring 40 and the wiring portion 50 are drawn, such as FIG. 3, a boundary portion between the inductor wiring 40 and the wiring portion 50 is indicated by a solid line.

As shown in FIG. 3, the wiring portion 50 includes a gate wiring portion 51, a source wiring portion 52, and a drain wiring portion 53.

The gate wiring portion 51 is in contact with the gate electrode 31 via a through hole 60 that penetrates the undoped region 331 of the channel layer 33 and the oxide film 32 in the thickness direction 101. In other words, the gate wiring portion 51 is electrically coupled to the gate electrode 31. The gate wiring portion 51 is an example of a variable resistance terminal.

A part of the source wiring portion 52 is covered with the electrode 411 of the one side part 41 of the inductor wiring 40. Accordingly, the source wiring portion 52 is electrically coupled to the one side part 41.

A part of the drain wiring portion 53 is covered with the electrode 421 of the other side part 42 of the inductor wiring 40. Accordingly, the drain wiring portion 53 is electrically coupled to the other side part 42. The source wiring portion 52 and the drain wiring portion 53 are examples of a pair of external terminals.

The inductor variable resistance portion 30, which is a MOSFET, functions as follows. The gate electrode 31 functions as a gate of the MOSFET. The one side part 41 functions as a source of the MOSFET. The other side part 42 functions as a drain of the MOSFET.

In the first embodiment, the inductor variable resistance portion 30, which is a MOSFET, is of a normally-on type. To make the inductor variable resistance portion 30 to be the normally-on type, Fermi levels of the gate electrode 31 and the channel material may be adjusted. For example, an impurity doping type or a doping amount may be adjusted. Further, for example, the gate electrode 31 may be aluminum gallium nitride (AlGaN), and the channel layer 33 may be gallium nitride (GaN). In the first embodiment, a low resistance portion is formed in the doped region 332. The low resistance portion is, for example, a part having a resistivity of 10⁻² Ω·cm or less in the channel layer 33.

Here, the low resistance portion is a part that exhibits a resistivity sufficiently lower than that of a semiconductor substrate (for example, the substrate 20 made of silicon). For example, the resistivity of the substrate 20 made of silicon is 10⁻³ Ω·cm. In a case where the resistivity is 1000 times or more lower than the resistivity of the substrate having this resistivity, most of the current flows to the low resistance portion. From the above, the low resistance portion may be a part having a resistivity of 10⁻² Ω·cm or less, as described above. In the first embodiment, impurity doping is performed to approximately 10²⁰ cm³. For example, in a case where the impurity is phosphorus, the low resistance portion has a resistivity of approximately 10⁻³ Ω·cm. Further, for example, in a case where the impurity is boron, the low resistance portion has a resistivity of approximately 5×10⁻³ Ω·cm.

With the formation of the low resistance portion in the doped region 332, the current flows to the doped region 332 even in a case where no voltage is applied between the gate and the source. In other words, even in a case where no voltage is applied between the gate electrode 31 and the one side part 41, the current flows between the one side part 41 and the other side part 42 through the doped region 332. The current that flows in the doped region 332 is larger as the voltage applied between the gate and the source is larger. In other words, the resistance value of the low resistance portion formed in the doped region 332 is smaller as the voltage applied between the gate electrode 31 and the one side part 41 is larger. That is, the inductor variable resistance portion 30 functions as a variable resistor whose resistance value changes according to the magnitude of the voltage applied between the gate electrode 31 and the one side part 41.

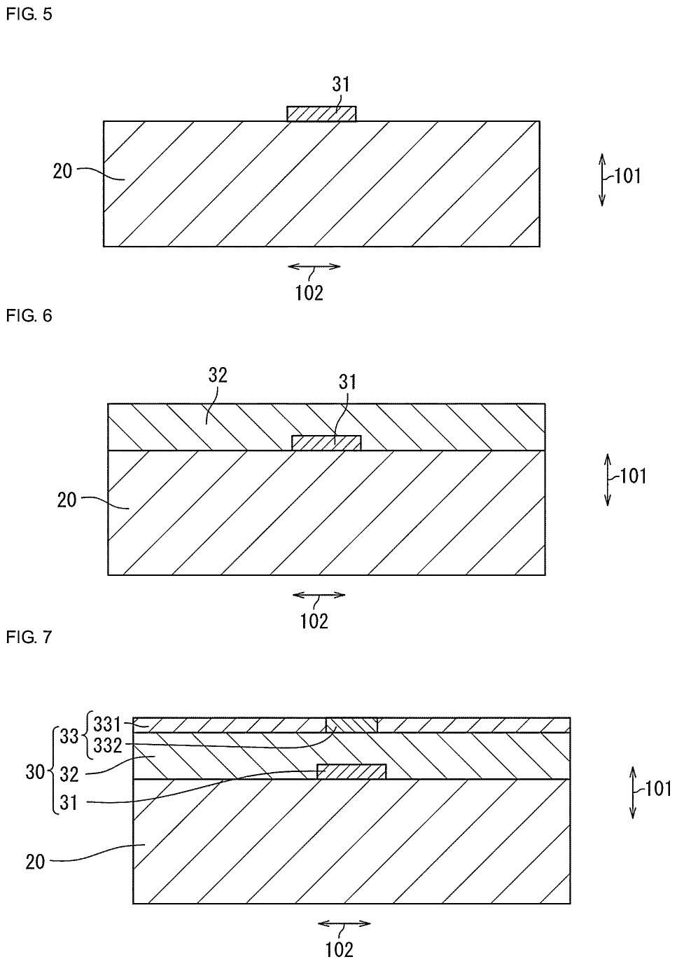

FIG. 5 is a schematic cross-sectional view describing a method of manufacturing the inductor element according to the first embodiment of the present disclosure. FIG. 6 is a schematic cross-sectional view describing the method of manufacturing the inductor element according to the first embodiment of the present disclosure. FIG. 7 is a schematic cross-sectional view describing the method of manufacturing the inductor element according to the first embodiment of the present disclosure.

The method of manufacturing the inductor element 10 will be described below with reference to FIGS. 5 to 7.

As shown in FIG. 5, the gate electrode 31 is laminated on the prepared substrate 20. A film is formed on the substrate 20 by a sputtering method. A resist is applied on the film. A pattern having the same shape as the gate electrode 31 described above is engraved on the resist by photolithography. After that, the resist is peeled off by etching. As described above, the gate electrode 31 with a desired shape is formed.

Next, as shown in FIG. 6, the oxide film 32 is formed on the surface of the substrate 20 on which the gate electrode 31 is formed. The oxide film 32 is formed by, for example, a chemical vapor deposition (CVD).

Next, as shown in FIG. 7, the channel layer 33 is formed on the oxide film 32. The channel layer 33 is formed by, for example, CVD. A resist is applied on the channel layer 33. A pattern of a region to be the doped region 332 is engraved on the resist by photolithography. Next, the P type and the N type impurities are doped at high concentrations. In this case, the doped region 332 not covered with the resist is doped with the impurities, and the undoped region 331 covered with the resist is not doped with the impurities. After that, the resist is peeled off by etching. Accordingly, the channel layer 33 is divided into the doped region 332 doped with the impurities and the undoped region 331 not doped with the impurities. After that, the through hole 60 (refer to FIG. 3) is formed in the channel layer 33.

Next, as shown in FIG. 3, the inductor wiring 40 and the wiring portion 50 are formed on the channel layer 33. In the wiring portion 50, a metal film (copper film in the first embodiment) is formed on the channel layer 33 by a sputtering method (for example, seed sputtering). A resist is applied on the metal film. A pattern having the same shape as the inductor wiring 40 and the wiring portion 50 described above is engraved on the resist by photolithography. Next, electrolytic plating is performed on the pattern and on the resist other than the pattern. The plating is not shown in FIG. 3. After that, the resist is peeled off by etching. Accordingly, the inductor wiring 40 and the wiring portion 50 having a desired shape and covered with plating are formed. The inductor wiring 40 and the wiring portion 50 may be formed at the same time as described above or may be formed separately.

According to the first embodiment, the inductor wiring 40 and the inductor variable resistance portion 30 form one coil. With the change in the resistance value of the inductor variable resistance portion 30, it is possible to change the impedance of the inductor element 10. In other words, there is no need to prepare a plurality of coils and switch between conduction and non-conduction of some or all of the plurality of coils to change the impedance of the inductor element. Therefore, it is possible to change the impedance of the inductor element 10 without changing the number of turns of the coil and a line length thereof. As a result, it is possible to suppress an increase in size of the inductor element 10. Further, since the impedance can be changed with one inductor element 10, there is no need to provide the inductor element 10 in a plurality of stages in the phase shifter 3.

In the variable inductor disclosed in Japanese Patent No. 6701923, the coil patterns are connected to each other with the outer electrodes interposed therebetween. For this reason, parasitic capacitance may be generated between the outer electrode and the coil pattern. According to the first embodiment, the inductor variable resistance portion 30 is directly connected to the inductor wiring 40 without an outer electrode or the like interposed therebetween. Therefore, it is possible to reduce the generation of parasitic capacitance.

In a case where the inductor variable resistance portion 30 is the MOSFET as in the first embodiment, it is possible to continuously control the resistance by the voltage applied to the gate electrode 31 of the MOSFET. Accordingly, it is possible to control the impedance of the inductor element 10 to a desired value. With the use of the MOSFET as the inductor variable resistance portion 30, it is easy to reduce the size of the inductor element 10.

The High-k material (for example, hafnium oxide) such as hafnium oxide (HfO₂) included in the oxide film 32 in the first embodiment has a high dielectric constant. Therefore, it is possible to increase the number of carriers excited in the channel layer.

With the provision of the metal oxide semiconductor such as indium tin oxide (ITO) as the material of the channel layer 33 at a desired position (doped region 332) as in the first embodiment, it is possible to form the channel layer 33 without doping. Accordingly, it is possible to form the channel layer 33 at low cost.

According to the first embodiment, the channel layer 33 contains a metal. Therefore, for example, it is possible to suppress formation of a low-dielectric constant layer between the oxide film 32 containing the High-k material and the channel layer 33. As a result, it is possible to increase the mobility of carriers in the channel layer 33.

According to the first embodiment, the entire channel layer 33 is made of amorphous silicon, and the doped region 332 is doped with P-type and N-type impurities at high concentrations. Therefore, it is possible to easily form the low resistance portion having low resistance in the doped region 332.

According to the first embodiment, the doped region 332 is in contact with both the one side part 41 and the other side part 42. Therefore, it is possible to easily form the low resistance portion between the one side part 41 and the other side part 42.

According to the first embodiment, the inductor variable resistance portion 30, which is a MOSFET, is of the normally-on type. Therefore, in a case where no voltage is applied to the gate electrode 31, it is possible to configure the inductor wiring 40 such that the current flows between the one side part 41 and the other side part 42. It is possible to increase the resistance between the one side part 41 and the other side part 42 as the voltage applied to the gate electrode 31 increases.

According to the first embodiment, with the change in the resistance of the inductor variable resistance portion 30 in one inductor element 10, it is possible to change the impedance of the inductor element 10. That is, according to the first embodiment, the integrated circuit does not need to have a plurality of inductors, unlike the variable inductor (variable inductor having the plurality of inductors) disclosed in Japanese Patent No. 6701923, Japanese Unexamined Patent Application No. 1996-162331, and Japanese Unexamined Patent Application No. 2010-272815. Therefore, it is possible to reduce the size of the integrated circuit 6.

In the variable inductor, which is disclosed in Japanese Patent No. 6701923, Japanese Unexamined Patent Application No. 1996-162331, and Japanese Unexamined Patent Application No. 2010-272815, with the change in the number of turns of the coil that functions and the line length thereof according to the on and off of the switch, the inductance of the variable inductor is adjusted, and the impedance is changed by the adjustment. On the contrary, in the variable inductor according to the first embodiment, with the adjustment of the resistance value of the inductor variable resistance portion 30 without changing the inductance of the inductor wiring 40, the impedance is changed. In an application such as a phase shifter included in a power transmission system, the influence of an increase in the resistance value on performance is relatively small, and thus the variable inductor as in the first embodiment is effective. The same applies to second to sixth embodiments described below.

The inductor element 10 may include a plurality of interruption portions 43. In this case, the inductor variable resistance portion 30 may be provided in correspondence with each of the plurality of interruption portions 43. In other words, the inductor element 10 may include a plurality of inductor variable resistance portions 30.

Depending on the material constituting the channel layer 33, the channel layer 33 is not always provided with the doped region 332. In other words, the channel layer 33 is not always doped with the impurity. For example, in a case where the channel layer 33 is made of the metal oxide semiconductor, the channel layer 33 is not always provided with the doped region 332.

At least one of the source wiring portion 52 or the drain wiring portion 53 and the gate wiring portion 51 may be integrally formed. For example, as indicated by one-dot chain line in FIG. 3, the drain wiring portion 53 may be connected to the gate wiring portion 51. Further, for example, the source wiring portion 52 may be connected to the gate wiring portion 51. As in a second embodiment described below, in a case of a configuration in which a plurality of gate wiring portions 51 are provided, at least one of the source wiring portion 52 or the drain wiring portion 53 and at least one of the gate wiring portions 51 may be integrally formed.

### Second Embodiment

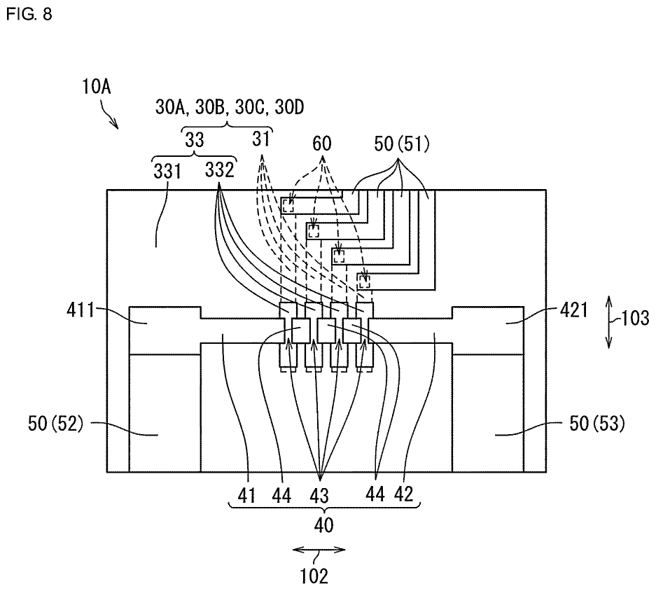

FIG. 8 is a schematic plan view of an inductor element according to the second embodiment of the present disclosure. An inductor element 10A according to the second embodiment is different from the inductor element 10 according to the first embodiment in that the inductor element 10A includes a plurality of inductor variable resistance portions 30A, 30B, 30C, and 30D, which are connected in series to each other. Hereinafter, the differences from the first embodiment will be described. Points in common with the inductor element 10 according to the first embodiment are attached with the same reference numerals, and the description thereof is omitted in principle and will be performed as necessary.

As shown in FIG. 8, the inductor element 10A includes the four inductor variable resistance portions 30A, 30B, 30C, and 30D. Each of the four inductor variable resistance portions 30A, 30B, 30C, and 30D is a MOSFET, similarly to the first embodiment, and includes the gate electrode 31, the oxide film 32, and the channel layer 33. The inductor element 10A includes four gate electrodes 31, one oxide film 32, and one channel layer 33. One channel layer 33 has one undoped region 331 and four doped regions 332. Each of the four gate electrodes 31 and each of the four doped regions 332 are provided in correspondence with the four inductor variable resistance portions 30A, 30B, 30C, and 30D. One oxide film 32 and one undoped region 331 are shared by the four inductor variable resistance portions 30A, 30B, 30C, and 30D.

The inductor wiring 40 is divided into five parts (one side part 41, the other side part 42, and three interdigitate portions 44) by four interruption portions 43. The three interdigitate portions 44 are located between the one side part 41 and the other side part 42. The five parts are provided side by side with spacings along the long-side direction 102. Each of the four interruption portions 43 is provided with each of the four doped regions 332. In a plan view, each of the four doped regions 332 overlaps two adjacent parts in the five parts. Each of the four gate electrodes 31 is disposed to face each of the four doped regions 332 in the thickness direction 101. The inductor element 10A includes four gate wiring portions 51. Each of the four gate electrodes 31 is in contact with each of the four gate wiring portions 51 via the through hole 60. With the configuration as described above, the inductor element 10A includes the plurality of inductor variable resistance portions 30A, 30B, 30C, and 30D, which are connected to each other in series.

According to the second embodiment, the inductor element 10A includes the plurality of inductor variable resistance portions 30A, 30B, 30C, and 30D, which are connected to each other in series. Therefore, it is possible to finely control the impedance of the inductor element 10A, as compared with the inductor element 10 including only one inductor variable resistance portion 30.

### Third Embodiment

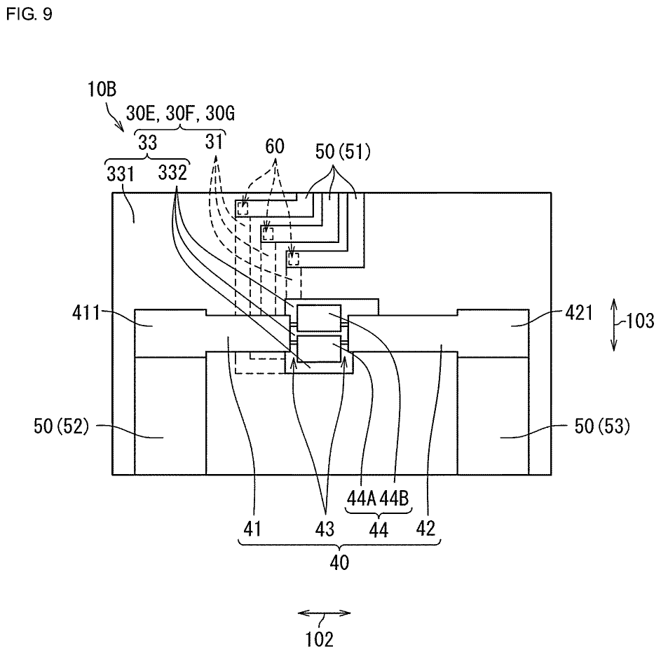

FIG. 9 is a schematic plan view of an inductor element according to a third embodiment of the present disclosure. An inductor element 10B according to the third embodiment is different from the inductor element 10 according to the first embodiment in that the inductor element 10B includes a plurality of inductor variable resistance portions 30E, 30F, and 30G, which are connected in parallel to each other. Hereinafter, the differences from the first embodiment will be described. Points in common with the inductor element 10 according to the first embodiment are attached with the same reference numerals, and the description thereof is omitted in principle and will be performed as necessary.

As shown in FIG. 9, the inductor element 10B includes the three inductor variable resistance portions 30E, 30F, and 30G. As in the first embodiment, each of the three inductor variable resistance portions 30E, 30F, and 30G includes the gate electrode 31, the oxide film 32, and the channel layer 33. The inductor element 10B includes three gate electrodes 31, one oxide film 32, and one channel layer 33. One channel layer 33 has one undoped region 331 and three doped regions 332. Each of the three gate electrodes 31 and each of the three doped regions 332 are provided in correspondence with the three inductor variable resistance portions 30E, 30F, and 30G. One oxide film 32 and one undoped region 331 are shared by the three inductor variable resistance portions 30E, 30F, and 30G.

The inductor wiring 40 is divided into three parts (one side part 41, the other side part 42, and one interdigitate portion 44) by two interruption portions 43. The interdigitate portion 44 is located between the one side part 41 and the other side part 42. The three parts are provided side by side with spacings along the long-side direction 102. One interdigitate portion 44 is divided into a first interdigitate portion 44A and a second interdigitate portion 44B, which are provided side by side with a spacing along the short-side direction 103. Each of the three doped regions 332 is provided over the three parts. In other words, in a plan view, each of the three doped regions 332 overlaps the three parts. Each of the three gate electrodes 31 is disposed to face each of the three doped regions 332 in the thickness direction 101. The inductor element 10B includes three gate wiring portions 51. Each of the three gate electrodes 31 is in contact with each of the three gate wiring portions 51 via the through hole 60. With the configuration as described above, the inductor element 10B includes the plurality of inductor variable resistance portions 30E, 30F, and 30G, which are connected in parallel to each other.

According to the third embodiment, the inductor element 10B includes the plurality of inductor variable resistance portions 30E, 30F, and 30G, which are connected in parallel to each other. Therefore, it is possible to finely control the impedance of the inductor element 10B, as compared with the inductor element 10 including only one inductor variable resistance portion 30.

### Fourth Embodiment

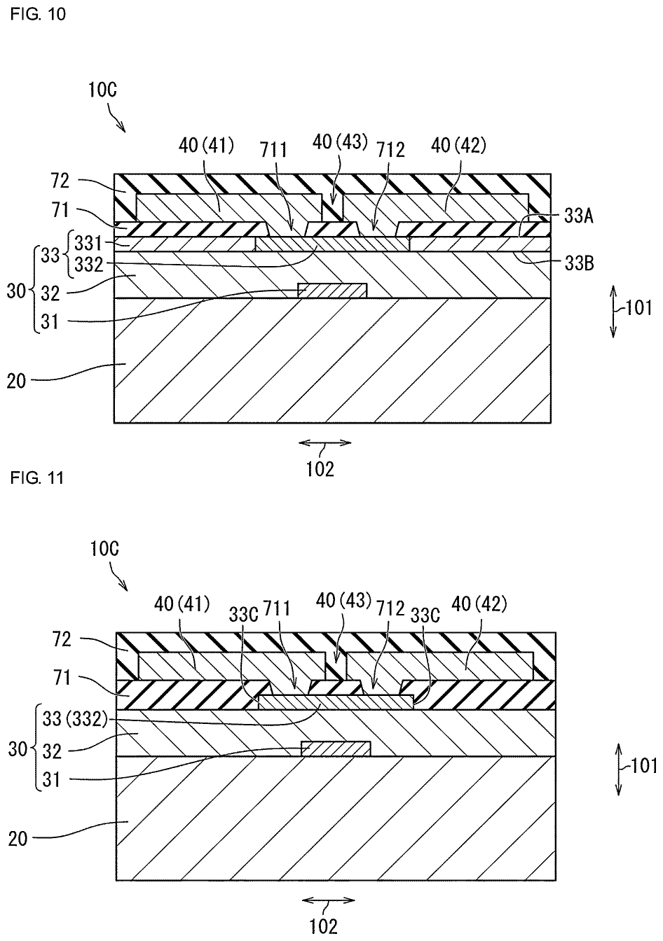

FIG. 10 is a schematic cross-sectional view of a cross section corresponding to the cross section taken along the line A-A in FIG. 3 in an inductor element according to a fourth embodiment of the present disclosure. An inductor element 10C according to the fourth embodiment is different from the inductor element 10 according to the first embodiment in that the inductor element 10C further includes an intervening insulation layer 71 and a covering insulation layer 72. Hereinafter, the differences from the first embodiment will be described. Points in common with the inductor element 10 according to the first embodiment are attached with the same reference numerals, and the description thereof is omitted in principle and will be performed as necessary.

As shown in FIG. 10, the inductor element 10C further includes the intervening insulation layer 71 and the covering insulation layer 72.

The intervening insulation layer 71 intervenes between the oxide film 32 and the inductor wiring 40 in the thickness direction 101. In the configuration shown in FIG. 10, the intervening insulation layer 71 intervenes between the channel layer 33 and the inductor wiring 40 in the thickness direction 101. The intervening insulation layer 71 is laminated on the channel layer 33. The inductor wiring 40 is laminated on the intervening insulation layer 71. The intervening insulation layer 71 is in contact with the inductor wiring 40.

The intervening insulation layer 71 has two through holes 711 and 712. Each of the two through holes 711 and 712 penetrates the intervening insulation layer 71 in the thickness direction 101.

In a plan view, the through hole 711 is at a position that overlaps both the one side part 41 of the inductor wiring 40 and the doped region 332 of the channel layer 33. In a plan view, the through hole 712 is at a position that overlaps both the other side part 42 of the inductor wiring 40 and the doped region 332 of the channel layer 33.

In a case where the metal film is formed on the channel layer 33 in a manufacturing process of the inductor element 10C, the metal film fills the through holes 711 and 712. The metal film filled in the through hole 711 becomes a part of the one side part 41, and the metal film filled in the through hole 712 becomes a part of the other side part 42. Accordingly, the one side part 41 is in contact with the doped region 332 via the through hole 711, and the other side part 42 is in contact with the doped region 332 via the through hole 712. As a result, even in a case where no voltage is applied between the gate electrode 31 and the one side part 41, the current flows between the one side part 41 and the other side part 42 through the doped region 332.

With the configuration as described above, the inductor wiring 40 covers a part of the channel layer 33 via the through holes 711 and 712.

A defect density of the channel layer 33 near an interface 33A between the intervening insulation layer 71 and the channel layer 33 is higher than the defect density of the channel layer 33 near an interface 33B between the oxide film 32 and the channel layer 33. The defect density is a ratio of crystal defects per unit volume constituting the channel layer 33 (in particular, the doped region 332).

The covering insulation layer 72 is provided on a side of the channel layer 33 opposite to the oxide film 32 in the thickness direction 101. The covering insulation layer 72 is laminated on the intervening insulation layer 71. The covering insulation layer 72 covers the inductor wiring 40.

In the fourth embodiment, the intervening insulation layer 71 is an inorganic insulation layer, and the covering insulation layer 72 is an organic insulation layer. The intervening insulation layer 71 is made of, for example, silicon dioxide (SiO₂) or silicon nitride (SiN). The covering insulation layer 72 is made of, for example, polyimide.

According to the fourth embodiment, with the intervening insulation layer 71 covering a part of the channel layer 33, it is possible to reduce the possibility that the channel layer 33 and the inductor wiring 40 are conducted to each other at an unintended position.

According to the fourth embodiment, the inductor wiring 40 is in contact with the channel layer 33 via the through holes 711 and 712. Therefore, with a change in positions of the through holes 711 and 712, it is possible to change a contact position between the inductor wiring 40 and the channel layer 33. In other words, it is possible to improve a degree of freedom in designing the inductor element 10.

A path through which the current passes is formed near the interface 33A with the intervening insulation layer 71 in the channel layer 33. In general, an increase in the defect density near the path is not preferable since the mobility of carriers of electrons or holes decreases. However, a property of the defect in the channel layer 33 that traps carriers generated on the channel layer 33 can be used. In other words, carriers near the path that cause eddy current loss generated at high frequency characteristics are trapped by the defect. Accordingly, it is possible to suppress a loss generated near the path. As a result, it is possible to suppress deterioration of a Q value in a high frequency region, and thus it is possible to provide the inductor element 10 having good high frequency characteristics.

According to the fourth embodiment, the inductor wiring 40 is protected by the covering insulation layer 72, and thus it is possible to reduce the possibility of damage of the inductor wiring 40. Accordingly, it is possible to improve the reliability of the inductor element 10.

In the configuration shown in FIG. 10, the intervening insulation layer 71 is laminated on the channel layer 33 and is separated from the oxide film 32. However, the intervening insulation layer 71 may be in contact with the oxide film 32. For example, as shown in FIG. 11, the intervening insulation layer 71 may be laminated on the oxide film 32 to cover the channel layer 33. FIG. 11 is a schematic cross-sectional view of a cross section corresponding to the cross section taken along the line A-A in FIG. 3 in a modification example of the inductor element according to the fourth embodiment of the present disclosure. In this case, the intervening insulation layer 71 covers a side surface 33C of the channel layer 33.

In the configuration shown in FIG. 11, the channel layer 33 is configured of only the doped region 332. However, the channel layer 33 may have the undoped region 331 and the doped region 332, or may be configured of only the undoped region 331. In a case where the channel layer 33 has the undoped region 331 and the doped region 332, for example, the doped region 332 is provided at a position that overlaps the through holes 711 and 712 in a plan view, and the undoped region 331 is provided at a position that overlaps the intervening insulation layer 71 in a plan view.

With the configuration shown in FIG. 11, the channel layer 33 can be formed in any region on the oxide film 32 by patterning the channel layer 33 on the oxide film 32. Therefore, it is possible to improve the degree of freedom in designing the inductor element 10.

In the configurations shown in FIGS. 10 and 11, the inductor element 10C includes the intervening insulation layer 71 and the covering insulation layer 72. However, the inductor element 10C may include only one of the intervening insulation layer 71 and the covering insulation layer 72.

### Fifth Embodiment

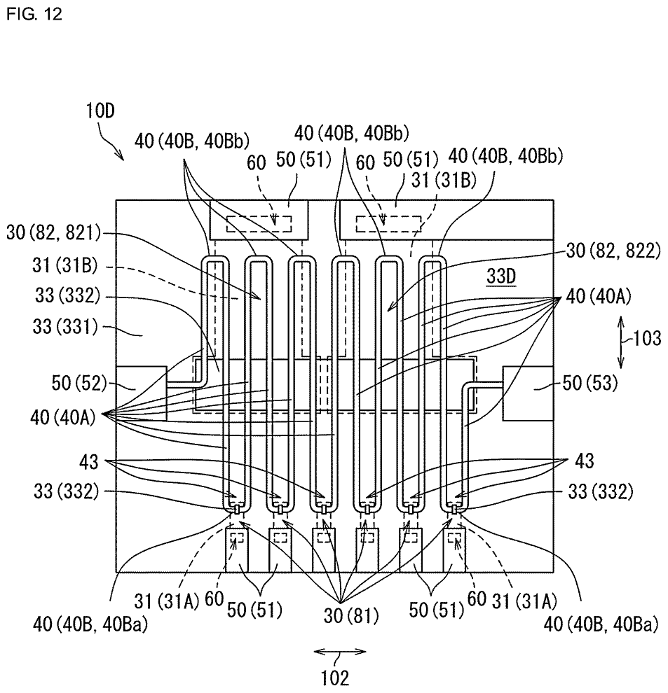

FIG. 12 is a schematic plan view of an inductor element according to a fifth embodiment of the present disclosure. A difference between an inductor element 10D according to the fifth embodiment and the inductor element 10 according to the first embodiment is the following point. In other words, the inductor element 10D includes a plurality of inductor variable resistance portions 30, and the plurality of inductor variable resistance portions 30 include a first variable resistance portion 81 and a second variable resistance portion 82. Hereinafter, the differences from the first embodiment will be described. Points in common with the inductor element 10 according to the first embodiment are attached with the same reference numerals, and the description thereof is omitted in principle and will be performed as necessary.

As shown in FIG. 12, the inductor wiring 40 included in the inductor element 10D extends while meandering on a plane (main surface 33D of the channel layer 33) that intersects (orthogonal in the fifth embodiment) the thickness direction 101. The main surface of the channel layer 33 is an example of an intersecting plane. The inductor wiring 40 has a meander shape, and includes 13 straight parts 40A that extend straight and 12 curved parts 40B that are curved. The 13 straight parts 40A and the 12 curved parts 40B are provided alternately and continuously. Each of the 13 straight parts 40A extends along the short-side direction 103 and is provided side by side with spacings in the long-side direction 102. The 12 curved parts 40B include six curved parts 40Ba each having the interruption portion 43, and six curved parts 40Bb each having no interruption portion 43.

In the fifth embodiment, a width of the inductor wiring 40 is 30 μm. The width of the inductor wiring 40 is a length in an extension direction of the inductor wiring 40 and in a direction orthogonal to the thickness direction 101. In the fifth embodiment, a thickness of the inductor wiring 40 is 30 μm. The thickness of the inductor wiring 40 is a length of the inductor wiring 40 in the thickness direction 101. In the fifth embodiment, a spacing between two adjacent straight parts 40A is 100 μm. The spacing between the two adjacent straight parts 40A is a length of a space between two adjacent straight parts 40A in the long-side direction 102.

The inductor element 10D includes eight inductor variable resistance portions 30. The eight inductor variable resistance portions 30 include six first variable resistance portions 81 and two second variable resistance portions 82 (second variable resistance portion 821 and second variable resistance portion 822).

The number of each of the inductor variable resistance portion 30, the first variable resistance portion 81, and the second variable resistance portion 82 is not limited to the above number. The inductor element 10D may include a plurality of inductor variable resistance portions 30. A part of the plurality of inductor variable resistance portions 30 may be the first variable resistance portion 81. Other than the part of the plurality of inductor variable resistance portions 30 may be the second variable resistance portion 82.

Each of the eight inductor variable resistance portions 30 is the MOSFET, similarly to each of the above-described embodiments, and includes the gate electrode 31, the oxide film 32, and the channel layer 33. The gate electrode 31 and the doped region 332 of the channel layer 33 are provided for each of the eight inductor variable resistance portions 30. The oxide film 32 and the undoped region 331 of the channel layer 33 are shared by the eight inductor variable resistance portions 30.

Similarly to the inductor variable resistance portion 30 in the first embodiment, in a plan view, a gate electrode 31A and the doped region 332 of each of the six first variable resistance portions 81 are provided at a position that overlaps the six interruption portions 43. Accordingly, similarly to the inductor variable resistance portion 30 in the first embodiment, the two parts of the inductor wiring 40 on both sides of the interruption portion 43 are conducted to each other with the first variable resistance portion 81 interposed therebetween. The gate electrode 31A of each of the six first variable resistance portions 81 faces the doped region 332 of each of the six first variable resistance portions 81 in the thickness direction 101. The gate electrode 31A of each of the six first variable resistance portions 81 is electrically coupled to the gate wiring portion 51 via the through hole 60. The gate electrode 31A of the first variable resistance portion 81 is an example of a first gate electrode.

The gate electrode 31 and the doped region 332 of the second variable resistance portions 821 and 822 are provided at a part of the inductor wiring 40 different from the interruption portion 43. In the configuration shown in FIG. 12, in a plan view, a gate electrode 31B and the doped region 332 of the second variable resistance portions 821 and 822 are provided at a part that overlaps the straight part 40A of the inductor wiring 40.

The doped region 332 of the second variable resistance portion 821 is provided straddling six straight parts 40A. The doped region 332 of the second variable resistance portion 822 is provided straddling seven straight parts 40A. The number of straight parts 40A straddled by the doped region 332 of the second variable resistance portion 82 is random. The number of second variable resistance portions 82 is random. For example, the number of straight parts 40A straddled by the doped region 332 of the second variable resistance portion 82 may be one. In this case, the inductor element 10D may include 12 second variable resistance portions 82, which is the number of the spaces between two adjacent straight parts 40A in the inductor wiring 40 shown in FIG. 12.

Here, two adjacent straight parts 40A in each of the 13 straight parts 40A face each other in the long-side direction 102. The long-side direction 102 is an example of a facing direction. One end portion of each of the 13 straight parts 40A is continuous with one end portion of an adjacent straight part 40A with the curved part 40Bb interposed therebetween. There is the curved part 40Ba between the other end portions of two adjacent straight parts 40A in the 13 straight parts 40A. In other words, the other end portions of two adjacent straight parts 40A are separated from each other by the interruption portion 43. From the above, two straight parts 40A (between a first part and a second part which will be described below) adjacent to each other with the curved part 40Bb interposed therebetween are connected by the inductor wiring 40. Further, two straight parts 40A (between a first part and a second part which will be described below) adjacent to each other with the curved part 40Ba interposed therebetween are connected by the inductor wiring 40 and the first variable resistance portion 81. The other end portion of one of two straight parts 40A located at both end portions of the inductor wiring 40 is connected to the source wiring portion 52 instead of the curved part 40Ba. One end portion of the other of the two straight parts 40A located at both end portions of the inductor wiring 40 is connected to the drain wiring portion 53 instead of the curved part 40Bb.

In a case where any two adjacent straight parts 40A in the six straight parts 40A are focused, the gate electrode 31B and the doped region 332 of the second variable resistance portion 821 extend as follows. In other words, in a plan view, the gate electrode 31B and the doped region 332 of the second variable resistance portion 821 extend along the long-side direction 102 from a position that overlaps one of the two straight parts 40A to a position that overlaps the other straight part 40A.

Similarly, in a case where any two adjacent straight parts 40A in the seven straight parts 40A are focused, the gate electrode 31B and the doped region 332 of the second variable resistance portion 822 extend as follows. In other words, in a plan view, the gate electrode 31B and the doped region 332 of the second variable resistance portion 822 extend along the long-side direction 102 from a position that overlaps one of the two straight parts 40A to a position that overlaps the other straight part 40A.

In this case, one of the two adjacent straight parts 40A is an example of the first part. The other of the two adjacent straight parts 40A is an example of the second part. The gate electrode 31B of the second variable resistance portion 822 is an example of a second gate electrode.

The doped regions 332 of the second variable resistance portions 821 and 822 are connected to the straight part 40A by being in contact with the straight part 40A at the position that overlaps each other in a plan view. Accordingly, the doped region 332 of the second variable resistance portions 821 and 822 extends from a position to be connected to the first part to a position to be connected to the second part along the long-side direction 102. In other words, the six straight parts 40A straddled by the doped region 332 of the second variable resistance portion 821 may be conducted to each other with the doped region 332 of the second variable resistance portion 821 interposed therebetween. The seven straight parts 40A straddled by the doped region 332 of the second variable resistance portion 822 may be conducted to each other with the doped region 332 of the second variable resistance portion 822 interposed therebetween.

The gate electrode 31B of each of the second variable resistance portions 821 and 822 faces the doped region 332 of each of the second variable resistance portions 821 and 822 in the thickness direction 101. The gate electrode 31B of each of the second variable resistance portions 821 and 822 is electrically coupled to the gate wiring portion 51 via the through hole 60.

In the fifth embodiment, the first variable resistance portion 81, which is a MOSFET, is of the normally-on type, and functions in the same manner as the inductor variable resistance portion 30 in the first embodiment. Thus, any further detailed description is omitted here.

In the fifth embodiment, the second variable resistance portions 821 and 822, which are MOSFETs, are of a normally-off type. The second variable resistance portions 821 and 822 function as follows. In a case where no voltage is applied between the gate and the source, the current does not flow in the doped region 332. In this case, between the source wiring portion 52 and the drain wiring portion 53, the current flows along the inductor wiring 40, that is, via the curved part 40B. On the other hand, in a case where the voltage is applied between the gate and the source, the low resistance portion is formed in the doped region 332. In this case, the resistance in the doped region 332 is lower than the resistance in the inductor wiring 40. For this reason, most of the current flows through the doped region 332 without passing through the curved part 40B. As a result, the number of times of meandering of the inductor wiring 40 having the meander shape is reduced, and the inductance and the impedance of the inductor element 10D change.

In the configuration shown in FIG. 12, in a case where no voltage is applied to the gate electrodes 31 of both the second variable resistance portions 821 and 822, the number of times of meandering of the inductor wiring 40 is 12 times. In a case where the voltage is applied to only one of the gate electrodes 31 of the second variable resistance portions 821 and 822, the number of times of meandering of the inductor wiring 40 is six times. In a case where the voltage is applied to both the gate electrodes 31 of the second variable resistance portions 821 and 822, the number of times of meandering of the inductor wiring 40 is zero times.

According to the fifth embodiment, with the change in the resistance value of the second variable resistance portion 82, it is possible to linearly connect the first part and the second part (two adjacent straight parts 40A). Accordingly, since the length and number of turns of the inductor wiring 40 change, it is possible to change the inductance of the inductor element 10D. As a result, it is possible to change the impedance of the inductor element 10D.

### Sixth Embodiment

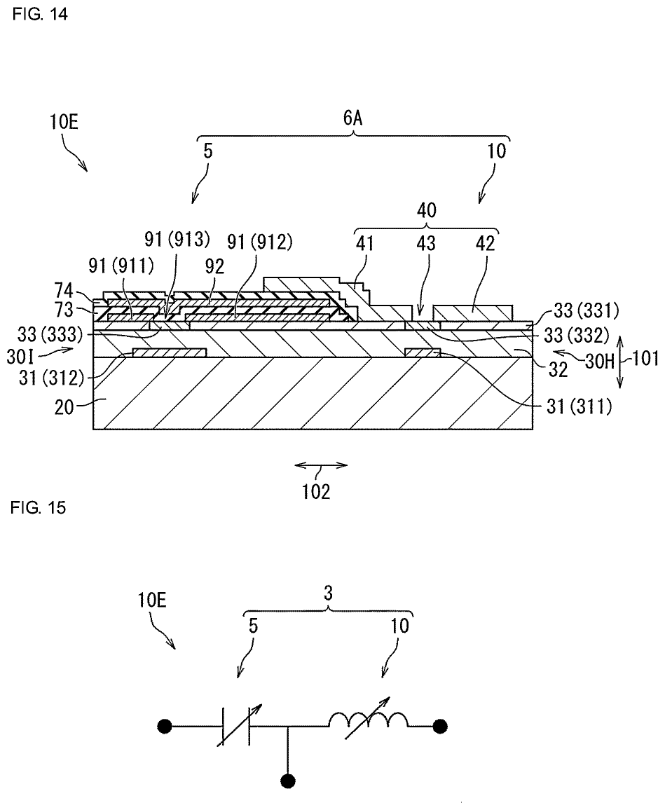

FIG. 13 is a schematic plan view of an integrated circuit according to a sixth embodiment of the present disclosure. FIG. 14 is a schematic cross-sectional view of a cross section taken along a line B-B in FIG. 13. FIG. 15 is an equivalent circuit diagram of the integrated circuit according to the sixth embodiment of the present disclosure.

As shown in FIGS. 13 and 14, an integrated circuit 6A according to the sixth embodiment is different from the integrated circuit 6 according to the first embodiment in that the integrated circuit 6A further includes the capacitor element 5 in addition to the inductor element 10. Hereinafter, the differences from the first embodiment will be described. Points in common with the integrated circuit 6 according to the first embodiment are attached with the same reference numerals, and the description thereof is omitted in principle and will be performed as necessary.

As shown in FIGS. 13 to 15, the integrated circuit 6A includes the inductor element 10 and the capacitor element 5.

As shown in FIG. 15, in the sixth embodiment, the inductor element 10 and the capacitor element 5 are connected in series. The inductor element 10 and the capacitor element 5 may be connected in parallel without being connected in series. As shown in FIG. 14, the inductor element 10 includes an inductor variable resistance portion 30H, and the capacitor element 5 includes a capacitor variable resistance portion 30I. Similarly to each of the above-described embodiments, the impedance is variable in the inductor element 10. As will be described below, an electrostatic capacity of the capacitor element 5 is variable.

As shown in FIGS. 13 and 14, the inductor variable resistance portion 30H and the capacitor variable resistance portion 30I are MOSFETs. The MOSFET includes the gate electrode 31, the oxide film 32, and the channel layer 33. The gate electrode 31 includes two gate electrodes 311 and 312. The channel layer 33 includes two doped regions 332 and 333.

The inductor variable resistance portion 30H includes the gate electrode 311, the oxide film 32, and the channel layer 33. The capacitor variable resistance portion 30I includes the gate electrode 312, the oxide film 32, and the channel layer 33. The gate electrode 312 is an example of an additional gate electrode. The oxide film 32 and the undoped region 331 of the channel layer 33 are shared by the inductor variable resistance portion 30H and the capacitor variable resistance portion 30I. The doped region 332 of the channel layer 33 is included in the inductor variable resistance portion 30H. The doped region 333 of the channel layer 33 is included in the capacitor variable resistance portion 30I.

The configuration of the inductor element 10 is the same configuration as that of the first embodiment. Thus, in the sixth embodiment, the description of the configuration of the inductor element 10 is omitted.

The capacitor element 5 includes the above-described capacitor variable resistance portion 30I, a pair of electrodes 91 and 92, insulation resistance layers 73 and 74, and the wiring portion 50 (specifically, an additional gate wiring portion 56 of the wiring portion 50, a capacitor wiring portion 57 and the source wiring portion 52). In the sixth embodiment, the source wiring portion 52 is shared by the capacitor element 5 and the inductor element 10.

The electrode 91, which is one of the pair of electrodes 91 and 92, is laminated on the channel layer 33. The electrode 91 is provided on a side of the channel layer 33 opposite to the oxide film 32 in the thickness direction 101 and is in contact with the channel layer 33. The electrode 91 includes an electrode 911 and an electrode 912. The electrodes 911 and 912 are provided with a gap 913 from each other in the long-side direction 102. In other words, the electrode 91 is divided into the plurality of parts with the gap 913 interposed therebetween. The electrode 92 is laminated on the insulation resistance layer 73. The electrode 92 faces the electrode 91 in the thickness direction 101.

A material forming the pair of electrodes 91 and 92 is different from the material forming the inductor wiring 40 of the inductor element 10. In the sixth embodiment, the pair of electrodes 91 and 92 are made of aluminum (Al), and the inductor wiring 40 is made of copper (Cu).

In a plan view, the doped region 333 is at a position that overlaps the gap 913. The doped region 333 is in contact with both the electrodes 911 and 912. In a plan view, the gate electrode 312 is at a position that overlaps the doped region 333.

The insulation resistance layer 73 is laminated on the channel layer 33 to cover the electrode 91. The insulation resistance layer 73 is located between the pair of electrodes 91 and 92.

The insulation resistance layer 74 is laminated on the insulation resistance layer 73 and the electrode 92 to cover the insulation resistance layer 73 and the electrode 92. The inductor wiring 40 is laminated on the insulation resistance layer 74. Accordingly, the pair of electrodes 91 and 92 are electrically insulated from the inductor wiring 40.

In the sixth embodiment, the insulation resistance layer 73 is an inorganic insulation layer, and the insulation resistance layer 74 is an organic insulation layer. The insulation resistance layer 73 is made of, for example, silicon dioxide (SiO₂) or silicon nitride (SiN). The insulation resistance layer 74 is made of, for example, polyimide.

The organic insulation layer is easily formed to be thicker than the inorganic insulation layer. Thus, with the provision of the insulation resistance layer 74, which is an organic insulation layer, between the pair of electrodes 91 and 92 and the inductor wiring 40, it is easy to enlarge a spacing between the pair of electrodes 91 and 92 and the inductor wiring 40.

The additional gate wiring portion 56 is electrically coupled to the gate electrode 312 via the through hole 60. The capacitor wiring portion 57 is electrically coupled to the electrode 911 via the through hole 60. The source wiring portion 52 is electrically coupled to the electrode 92 via the through hole 60.

The capacitor variable resistance portion 30I, which is a MOSFET, functions as follows. The gate electrode 312 functions as a gate of the MOSFET. The electrode 911 functions as a drain of the MOSFET. The one side part 41 of the inductor element 10 functions as a source of the MOSFET.

In the sixth embodiment, the capacitor variable resistance portion 30I, which is a MOSFET, is of the normally-off type. In a case where no voltage is applied between the gate and the source, the current does not flow in the doped region 333. In this case, a capacitor is configured by the electrode 911 of the electrodes 91 and the electrode 92. In other words, a charge is accumulated between the electrode 911 and the electrode 92. On the other hand, in a case where the voltage is applied between the gate and the source, the low resistance portion is formed in the doped region 333. For this reason, the current flows from the electrode 911 to the electrode 912 through the doped region 333. In this case, a capacitor is configured by the entire electrode 91 (electrodes 911 and 912) and the electrode 92. In other words, the charge is accumulated between the electrodes 911 and 912 and the electrode 92. That is, depending on the presence or absence of the voltage application to the gate electrode 312, the resistance value with respect to the current flowing through the electrode 91 can be changed. It is possible to change the electrostatic capacity of the capacitor with the change in the resistance value.

The capacitor variable resistance portion 30I, which is a MOSFET, may be of the normally-on type in a case where a carrier concentration of the channel layer 33 is high. Further, in the sixth embodiment, both the inductor variable resistance portion 30H and the capacitor variable resistance portion 30I are MOSFETs. However, the inductor variable resistance portion 30H and the capacitor variable resistance portion 30I may be transistors of different types. For example, the inductor variable resistance portion 30H may be the MOSFET, and the capacitor variable resistance portion 30I may be a bipolar transistor. Further, for example, both the inductor variable resistance portion 30H and the capacitor variable resistance portion 30I are the MOSFETs, but a channel width or length may be different. Further, in the sixth embodiment, the inductor variable resistance portion 30H and the capacitor variable resistance portion 30I have a common oxide film, but each may have an oxide film individually.

According to the sixth embodiment, the integrated circuit 6A includes the capacitor element 5 in addition to the inductor element 10. Therefore, it is possible to improve a degree of freedom in designing the integrated circuit 6A, and thus it is possible to provide the integrated circuit 6A having a wider variety of functions.

According to the sixth embodiment, with the control of the voltage application to the gate electrode 312, it is possible to change the impedance of the capacitor element 5.

According to the sixth embodiment, the material forming the pair of electrodes 91 and 92 of the capacitor element 5 is different from the material forming the inductor wiring 40 of the inductor element 10. Accordingly, it is possible to select an optimum material for each of the pair of electrodes 91 and 92 and the inductor wiring 40. As a result, it is possible to reduce costs of the integrated circuit 6A.

A part of the channel layer 33 may also serve as one of the pair of electrodes 91 and 92.

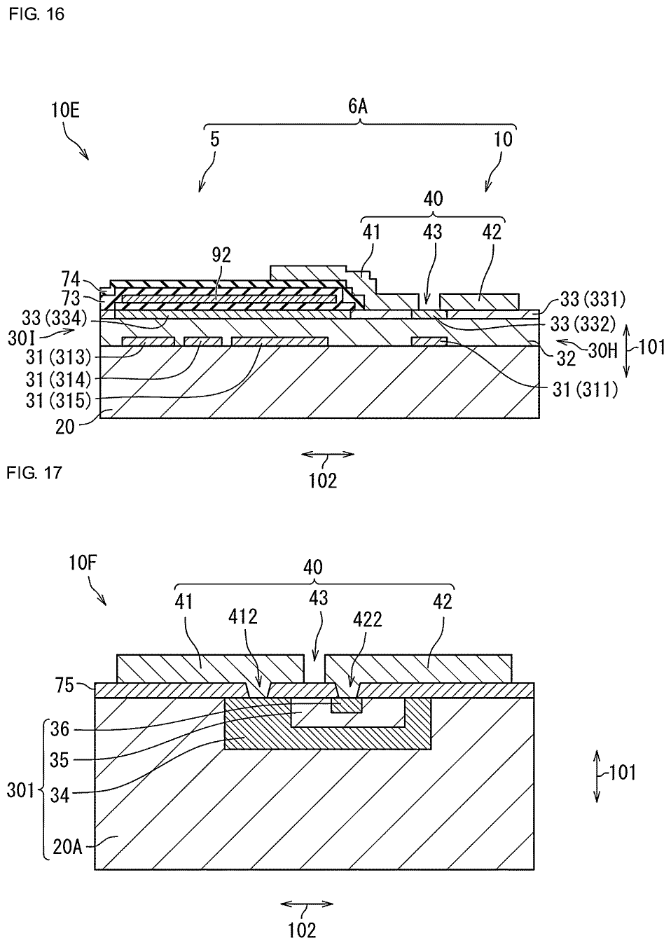

FIG. 16 is a schematic cross-sectional view of a cross section corresponding to the cross section taken along the line B-B in FIG. 13 in a modification example of the integrated circuit according to the sixth embodiment of the present disclosure. In the configuration shown in FIG. 16, a part of the channel layer 33 also serves as the electrode 91.

The channel layer 33 has a doped region 334. The doped region 334 also serves as the electrode 91.

The capacitor element 5 has three gate electrodes 313, 314, and 315 as the gate electrode 31. The gate electrodes 313, 314, and 315 are examples of the additional gate electrode. The gate electrodes 313, 314, and 315 face the doped region 334 in the thickness direction 101. In other words, in a plan view, the gate electrodes 313, 314, and 315 are at a position that overlaps the doped region 334. The voltage is individually applied to each of the three gate electrodes 313, 314, and 315. The number of gate electrodes of the capacitor element 5 is not limited to three.

In the configuration shown in FIG. 16, the capacitor variable resistance portion 30I, which is a MOSFET, is of the normally-off type. The current flows into a part of the doped region 334 that faces an electrode to which the voltage is applied in the three gate electrodes 313, 314, and 315. Accordingly, a capacitor is configured by the part and the electrode 92. In other words, the charge is accumulated between the portion and the electrode 92. For example, the electrostatic capacity of the capacitor in a case where the voltage is applied to all the three gate electrodes 313, 314, and 315 is larger than the electrostatic capacity of the capacitor in a case where the voltage is applied to the two gate electrodes 313 and 314.

According to the sixth embodiment, the doped region 333, which is a part of the channel layer 33, also serves as one of the pair of electrodes. Therefore, in a manufacturing process of the integrated circuit 6A, it is possible to omit a step of forming one of the pair of electrodes. As a result, it is possible to reduce the costs of the integrated circuit 6A.

The number of capacitor elements 5 included in the integrated circuit 6A is not limited to one. The number of capacitor variable resistance portions 30I included in the capacitor element 5 is not limited to one.

In each of the above-described embodiments, an example has been described in which the inductor variable resistance portion 30 (30A to 30H) is the MOSFET, but the inductor variable resistance portion 30 (30A to 30H) is not limited to the MOSFET.

For example, as shown in FIG. 17, an inductor variable resistance portion 30I included in an inductor element 10F may be a bipolar transistor. FIG. 17 is a schematic cross-sectional view of a cross section corresponding to the cross section taken along the line A-A in FIG. 3 in an inductor element according to a seventh embodiment of the present disclosure.

As shown in FIG. 17, the inductor variable resistance portion 30I includes a substrate 20A, a collector layer 34, a base layer 35, and an emitter layer 36. The substrate 20A is doped to P-type and made of silicon (Si). The collector layer 34 is formed on the substrate 20A and doped to N type. The base layer 35 is formed on the collector layer 34 and is doped to P-type. The emitter layer 36 is formed on the base layer 35 and is doped N-type. The insulation layer 75 is laminated on the substrate 20A to cover the collector layer 34, the base layer 35, and the emitter layer 36. The inductor wiring 40 is laminated on the insulation layer 75. The one side part 41 of the inductor wiring 40 is electrically coupled to the collector layer 34 via a through hole 412 that penetrates the insulation layer 75 in the thickness direction 101. The other side part 42 of the inductor wiring 40 is electrically coupled to the emitter layer 36 via a through hole 422 that penetrates the insulation layer 75 in the thickness direction 101. The inductor variable resistance portion 301 having the above configuration is manufactured by a known method.

In the configuration shown in FIG. 17, a base current is amplified by controlling a potential difference between a collector and a base. With the control of the potential difference, it is possible to control the resistance in the inductor variable resistance portion 301.

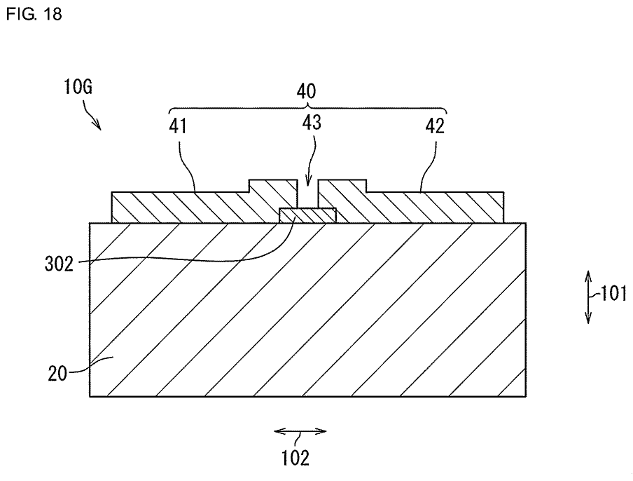

For example, as shown in FIG. 18, an inductor variable resistance portion 302 included in an inductor element 10G may be a photoresistor. In other words, the inductor variable resistance portion is not limited to the transistor. FIG. 18 is a schematic cross-sectional view of a cross section corresponding to the cross section taken along the line A-A in FIG. 3 in an inductor element according to an eighth embodiment of the present disclosure.

As shown in FIG. 18, the inductor variable resistance portion 302 is a cadmium sulfide (CdS) layer laminated on a part of the substrate 20. For example, the cadmium sulfide layer may be formed at a necessary place on the substrate 20 by using a printing sintering method used for manufacturing a solar cell or the like. Further, for example, the cadmium sulfide layer may be formed on the entire surface on the substrate 20, and then the cadmium sulfide layer may be left only at the necessary place by a known method such as etching.

A part of the one side part 41 of the inductor wiring 40 is in contact with the inductor variable resistance portion 302 (cadmium sulfide layer). A part of the other side part 42 of the inductor wiring 40 is in contact with the inductor variable resistance portion 302. The one side part 41 and the other side part 42 are formed with the interruption portion 43 therebetween. The inductor variable resistance portion 302 is formed straddling the interruption portion 43 in a plan view.

In the configuration shown in FIG. 18, it is possible to control the resistance in the inductor variable resistance portion 302 according to an amount of light emitted to the inductor variable resistance portion 302. For example, the resistance is larger as the amount of light is smaller.

The capacitor variable resistance portion 30I is not limited to the MOSFET, similarly to the inductor variable resistance portions 30A to 30H.

The inductor element and the integrated circuit described above can also be expressed as follows.

(1) An inductor element of one aspect of the present disclosure includes an inductor wiring having an interruption portion in at least one place, a pair of external terminals that are connected to each of one side part and the other side part, which are located on both sides of the interruption portion, of the inductor wiring and that are exposed to an outside, at least one inductor variable resistance portion that is provided at the interruption portion, and at least one variable resistance terminal that is connected to the inductor variable resistance portion and that is exposed to the outside. The inductor variable resistance portion connects the one side part and the other side part, and changes a resistance value between the one side part and the other side part.

(2) In the inductor element of (1), the inductor variable resistance portion may be a MOSFET, the inductor variable resistance portion, which is the MOSFET, may include an oxide film, a gate electrode that is provided on one main surface side of the oxide film in contact with the oxide film and that is at a position that overlaps the interruption portion as viewed from a thickness direction of the inductor variable resistance portion, which is the MOSFET, and a channel layer that is provided on the other main surface side of the oxide film in contact with the oxide film. The inductor wiring may be provided on a side of the channel layer opposite to the oxide film in the thickness direction and may be in contact with the channel layer.

(3) In the inductor element of (2), the oxide film may include a High-k material.

(4) In the inductor element of (3), the High-k material may be hafnium oxide.

(5) In the inductor element of any one of (2) to (4), the channel layer may include a metal oxide semiconductor.

(6) In the inductor element of any one of (2) to (4), the channel layer may have a doped region where amorphous silicon is contained and an impurity is doped, and the doped region may overlap the interruption portion as viewed from the thickness direction.

(7) In the inductor element of any one of (2) to (4), the channel layer may have a doped region where a metal oxide semiconductor is contained and an impurity is doped, and the doped region may overlap the interruption portion as viewed from the thickness direction.

(8) In the inductor element of (6) or (7), the doped region may be in contact with both the one side part and the other side part.

(9) In the inductor element of any one of (2) to (8), the inductor variable resistance portion, which is the MOSFET, may be of a normally-on type.

(10) The inductor element of any one of (2) to (9) may further include an intervening insulation layer that intervenes between the oxide film and the inductor wiring in the thickness direction to be in contact with the inductor wiring, and that covers a part of the channel layer. The intervening insulation layer may have a through hole that penetrates the intervening insulation layer in the thickness direction, and the inductor wiring may be in contact with the channel layer via the through hole.

(11) In the inductor element of (10), a defect density of the channel layer near an interface between the intervening insulation layer and the channel layer may be higher than the defect density of the channel layer near an interface between the oxide film and the channel layer.

(12) In the inductor element of (10) or (11), the intervening insulation layer may cover a side surface of the channel layer.

(13) The inductor element of any one of (2) to (12) may further include a covering insulation layer that is provided on a side of the channel layer opposite to the oxide film in the thickness direction and that covers the inductor wiring.

(14) In the inductor element of any one of (1) to (13), in which a plurality of the inductor variable resistance portions are provided, and the plurality of inductor variable resistance portions may be connected in series.

(15) In the inductor element of any one of (1) to (13), in which a plurality of the inductor variable resistance portions are provided, and the plurality of inductor variable resistance portions may be connected in parallel.

(16) In the inductor element of any one of (1) to (15), in which a plurality of the inductor variable resistance portions are provided. A part of the plurality of inductor variable resistance portions may be a first variable resistance portion that is provided at the interruption portion in the inductor wiring, a part other than the part of the plurality of inductor variable resistance portions may be a second variable resistance portion that is provided at a part of the inductor wiring different from the interruption portion, the inductor wiring may have a first part and a second part that is continuous with the first part without the interruption portion interposed therebetween and faces the first part in a facing direction, and the second variable resistance portion may extend from a position to be connected to the first part to a position to be connected to the second part along the facing direction.

(17) In the inductor element of (16), the inductor variable resistance portion may be a MOSFET. The first variable resistance portion of the inductor variable resistance portion, which is the MOSFET, may include an oxide film, a first gate electrode that is provided on one main surface side of the oxide film in contact with the oxide film and that is at a position that overlaps the interruption portion as viewed from a thickness direction of the inductor variable resistance portion, which is the MOSFET, and a channel layer that is provided on the other main surface side of the oxide film in contact with the oxide film. The second variable resistance portion of the inductor variable resistance portion, which is the MOSFET, may include the oxide film, a second gate electrode that is provided on one main surface side of the oxide film in contact with the oxide film and that is at a position that overlaps a part different from the interruption portion as viewed from the thickness direction, and the channel layer. The inductor wiring may be provided on a side of the channel layer opposite to the oxide film in the thickness direction to be in contact with the channel layer, and may extend on an intersecting plane that intersects with the facing direction, and the second gate electrode may extend from the first part to the second part along the facing direction.

(18) In the inductor element of any one of (1) to (17), at least one of the external terminals and at least one of the variable resistance terminals may be integrally formed.

(19) An integrated circuit of one aspect of the present disclosure includes the inductor element of any one of (1) to (18), and a control section that controls the resistance value of the inductor variable resistance portion.

(20) The integrated circuit of (19) may further include a capacitor element that has a pair of electrodes facing each other and at least one capacitor variable resistance portion, in which the capacitor variable resistance portion may change a resistance value with respect to a current that flows through the pair of electrodes to change an electrostatic capacity of the capacitor element.

(21) In the integrated circuit of (20), the inductor variable resistance portion may be a MOSFET. The inductor variable resistance portion, which is the MOSFET, may include an oxide film, a gate electrode that is provided on one main surface side of the oxide film in contact with the oxide film and that is at a position that overlaps the interruption portion as viewed from a thickness direction of the inductor variable resistance portion, which is the MOSFET, and a channel layer that is provided on the other main surface side of the oxide film in contact with the oxide film. The capacitor variable resistance portion may be the MOSFET. The capacitor variable resistance portion, which is the MOSFET, may include the oxide film, an additional gate electrode that is provided on one main surface side of the oxide film in contact with the oxide film, and the channel layer. The pair of electrodes may face each other in the thickness direction, one of the pair of electrodes may be provided on a side of the channel layer opposite to the oxide film in the thickness direction to be in contact with the channel layer, and may be divided into a plurality of parts with a gap therebetween, and the additional gate electrode may be at a position that overlaps the gap as viewed from the thickness direction.

(22) In the integrated circuit of (20), the inductor variable resistance portion may be a MOSFET. The inductor variable resistance portion, which is the MOSFET, may include an oxide film, a gate electrode that is provided on one main surface side of the oxide film in contact with the oxide film and that is at a position that overlaps the interruption portion as viewed from a thickness direction of the inductor variable resistance portion, which is the MOSFET, and a channel layer that is provided on the other main surface side of the oxide film in contact with the oxide film. The capacitor variable resistance portion may be the MOSFET. The capacitor variable resistance portion, which is the MOSFET, may include the oxide film, an additional gate electrode that is provided on one main surface side of the oxide film in contact with the oxide film, and the channel layer. The pair of electrodes may face each other in the thickness direction, a part of the channel layer may also serve as one of the pair of electrodes, and the additional gate electrode may be at a position that overlaps a part of the channel layer that also serves as one of the pair of electrodes, as viewed from the thickness direction.

(23) In the inductor element of any one of (20) to (22), a material forming the pair of electrodes of the capacitor element may be different from a material forming the inductor wiring of the inductor element.

With a combination of any embodiments of the various embodiments as appropriate, it is possible to achieve the respective effects.

Although the present disclosure has been sufficiently described in connection with the preferred embodiments with reference to the drawings as appropriate, various modifications or changes are apparent to those skilled in the art. It should be understood that such modifications or changes are included therein without departing from the scope of the present disclosure according to the attached claims.

What is claimed is:

1. An inductor element comprising:
an inductor wiring having an interruption portion in at least one place;
a pair of external terminals that are connected to each of one side part and the other side part, which are located on both sides of the interruption portion, of the inductor wiring and that are exposed to an outside;
at least one inductor variable resistance portion that is at the interruption portion; and
at least one variable resistance terminal that is connected to the inductor variable resistance portion and that is exposed to the outside,
wherein the inductor variable resistance portion connects the one side part and the other side part, and is configured to change a resistance value between the one side part and the other side part.

2. The inductor element according to claim 1, wherein
the inductor variable resistance portion is a MOSFET,
the inductor variable resistance portion, which is the MOSFET, includes
an oxide film,
a gate electrode that is on one main surface side of the oxide film in contact with the oxide film and that is at a position that overlaps the interruption portion as viewed from a thickness direction of the inductor variable resistance portion, which is the MOSFET, and
a channel layer that is on the other main surface side of the oxide film in contact with the oxide film, and
the inductor wiring is on a side of the channel layer opposite to the oxide film in the thickness direction and is in contact with the channel layer.

3. The inductor element according to claim 2, wherein
the channel layer has a doped region where an impurity is doped, and
the doped region is in contact with both the one side part and the other side part.

4. The inductor element according to claim 2, wherein
the inductor variable resistance portion, which is the MOSFET, is of a normally-on type.

5. The inductor element according to claim 2, further comprising:
an intervening insulation layer that intervenes between the oxide film and the inductor wiring in the thickness direction to be in contact with the inductor wiring, and that covers a part of the channel layer,
wherein
the intervening insulation layer has a through hole that penetrates the intervening insulation layer in the thickness direction, and
the inductor wiring is in contact with the channel layer via the through hole.

6. The inductor element according to claim 5, wherein
a defect density of the channel layer near an interface between the intervening insulation layer and the channel layer is higher than a defect density of the channel layer near an interface between the oxide film and the channel layer.

7. The inductor element according to claim 5, wherein
the intervening insulation layer covers a side surface of the channel layer.

8. The inductor element according to claim 2, further comprising:
a covering insulation layer that is on a side of the channel layer opposite to the oxide film in the thickness direction and that covers the inductor wiring.

9. The inductor element according to claim 1, wherein
the at least one inductor variable resistance portions is a plurality of the inductor variable resistance portions, and
the plurality of inductor variable resistance portions are connected in series.

10. The inductor element according to claim 1, wherein
the at least one inductor variable resistance portions is a plurality of the inductor variable resistance portions, and
the plurality of inductor variable resistance portions are connected in parallel.

11. The inductor element according to claim 1, wherein
the at least one inductor variable resistance portions is a plurality of the inductor variable resistance portions,
a part of the plurality of inductor variable resistance portions is a first variable resistance portion that is at the interruption portion in the inductor wiring,
a part other than the part of the plurality of inductor variable resistance portions is a second variable resistance portion that is at a part of the inductor wiring different from the interruption portion,
the inductor wiring has a first part and a second part that faces the first part in a facing direction without another part of the inductor wiring interposed therebetween,
the first part and the second part of the inductor wiring are connected by the inductor wiring or by the inductor wiring and the first variable resistance portion, and
the second variable resistance portion extends from a position to be connected to the first part to a position to connect to the second part along the facing direction.

12. The inductor element according to claim 11, wherein
the inductor variable resistance portion is a MOSFET,
the first variable resistance portion of the inductor variable resistance portion, which is the MOSFET, includes
an oxide film,
a first gate electrode that is on one main surface side of the oxide film in contact with the oxide film and that is at a position that overlaps the interruption portion as viewed from a thickness direction of the inductor variable resistance portion, which is the MOSFET, and
a channel layer that is on the other main surface side of the oxide film in contact with the oxide film,
the second variable resistance portion of the inductor variable resistance portion, which is the MOSFET, includes
the oxide film,
a second gate electrode that is on one main surface side of the oxide film in contact with the oxide film and that is at a position that overlaps a part different from the interruption portion as viewed from the thickness direction, and
the channel layer,
the inductor wiring is on a side of the channel layer opposite to the oxide film in the thickness direction to be in contact with the channel layer, and extends on an intersecting plane that intersects with the facing direction, and
the second gate electrode extends from the first part to the second part along the facing direction.

13. The inductor element according to claim 1, wherein
at least one of the external terminals and at least one of the variable resistance terminals are integral.

14. An integrated circuit comprising:
the inductor element according to claim 1; and
a controller configured to control the resistance value of the inductor variable resistance portion.

15. The integrated circuit according to claim 14, further comprising:
a capacitor element that has a pair of electrodes facing each other and at least one capacitor variable resistance portion,
wherein the capacitor variable resistance portion is configured to change a resistance value with respect to a current that flows through the pair of electrodes to change an electrostatic capacity of the capacitor element.

16. The integrated circuit according to claim 15, wherein
the inductor variable resistance portion is a MOSFET,
the inductor variable resistance portion, which is the MOSFET, includes
an oxide film,
a gate electrode that is on one main surface side of the oxide film in contact with the oxide film and that is at a position that overlaps the interruption portion as viewed from a thickness direction of the inductor variable resistance portion, which is the MOSFET, and
a channel layer that is on the other main surface side of the oxide film in contact with the oxide film,
the capacitor variable resistance portion is the MOSFET,
the capacitor variable resistance portion, which is the MOSFET, includes
the oxide film,
an additional gate electrode that is on one main surface side of the oxide film in contact with the oxide film, and
the channel layer,
the pair of electrodes faces each other in the thickness direction,
one of the pair of electrodes is on a side of the channel layer opposite to the oxide film in the thickness direction to be in contact with the channel layer, and is divided into a plurality of parts with a gap therebetween, and
the additional gate electrode is at a position that overlaps the gap as viewed from the thickness direction.

17. The integrated circuit according to claim 15, wherein
the inductor variable resistance portion is a MOSFET,
the inductor variable resistance portion, which is the MOSFET, includes
an oxide film,
a gate electrode that is on one main surface side of the oxide film in contact with the oxide film and that is at a position that overlaps the interruption portion as viewed from a thickness direction of the inductor variable resistance portion, which is the MOSFET, and
a channel layer that is on the other main surface side of the oxide film in contact with the oxide film,
the capacitor variable resistance portion is the MOSFET,
the capacitor variable resistance portion, which is the MOSFET, includes
the oxide film,
an additional gate electrode that is on one main surface side of the oxide film in contact with the oxide film, and
the channel layer,
the pair of electrodes faces each other in the thickness direction,
a part of the channel layer also serves as one of the pair of electrodes, and
the additional gate electrode is at a position that overlaps a part of the channel layer that also serves as one of the pair of electrodes, as viewed from the thickness direction.

18. The integrated circuit according to claim 15, wherein
a material of the pair of electrodes of the capacitor element is different from a material of the inductor wiring of the inductor element.

19. The inductor element according to claim 3, wherein
the inductor variable resistance portion, which is the MOSFET, is of a normally-on type.

20. The inductor element according to claim 3, further comprising:
an intervening insulation layer that intervenes between the oxide film and the inductor wiring in the thickness direction to be in contact with the inductor wiring, and that covers a part of the channel layer,
wherein
the intervening insulation layer has a through hole that penetrates the intervening insulation layer in the thickness direction, and
the inductor wiring is in contact with the channel layer via the through hole.
